(19) United States
(12) Patent Application Publication
(10) Pub. No.: US 2023/0060319 A1
(43) Pub. Date: Mar. 2, 2023

(54) DISPLAY PANEL, METHOD FOR MANUFACTURING THE SAME, AND DISPLAY APPARATUS

(71) Applicant: Shanghai Tianma Micro-Electronics Co., Ltd., Shanghai (CN)

(72) Inventors: Chen Chen, Shanghai (CN); Mengmeng Xie, Shanghai (CN)

(73) Assignee: Shanghai Tianma Micro-Electronics Co., Ltd., Shanghai (CN)

(21) Appl. No.: 18/053,444

(22) Filed: Nov. 8, 2022

(30) Foreign Application Priority Data
Jun. 28, 2022 (CN) 202210751894.2

(51) Int. Cl. H01L 33/62; H01L 25/075

(52) U.S. Cl. CPC H01L 33/62; H01L 25/0753; H01L 2933/0066

(57) ABSTRACT

A display panel and a method for manufacturing the display panel and a display apparatus are provided. In an embodiment, the display panel includes a substrate, a first connecting electrode provided on a side of the substrate, and a light-emitting device including at least one second connecting electrode. In an embodiment, conductive particles are provided between the second connecting electrode and the first connecting electrode. In an embodiment, the first connecting electrode and the light-emitting device are connected by a connecting structure. In an embodiment, the connecting structure is provided between the first connecting electrode and the second connecting electrode, and/or, the connecting structure is provided on a sidewall of the first connecting electrode and a sidewall of the second connecting electrode.

### CROSS-REFERENCE TO RELATED APPLICATION

The present application claims to the benefit of Chinese Patent Application No. 202210751894.2, filed on Jun. 28, 2022, the content of which is incorporated herein by reference in its entirety.

### TECHNICAL FIELD

The present disclosure relates to the field of display technologies, and in particular, to a display panel, a method for manufacturing the display panel, and a display apparatus.

### BACKGROUND

As a new generation of display technology, a Micro-light-emitting diode (LED) display panel and a Mini LED display panel have significant advantages of better brightness, better lighting efficiency, and lower power consumption. Different from a manufacturing manner of an organic light-emitting diode (OLED) display panel in which film deposition is adopted, light-emitting devices arranged in a matrix in the Micro-LED display panel and the Mini LED display panel mainly realized by a soft seal transfer technology. However, in the Micro-LED display panel and the Mini LED display panel prepared by using the soft seal transfer technology, assembling technology of light-emitting devices and the substrate is still not mature.

### SUMMARY

In a first aspect, an embodiment of the present disclosure provides a display panel. In an embodiment, the display panel includes a substrate; a first connecting electrode provided on a side of the substrate; and a light-emitting device. In an embodiment, the light-emitting device includes at least one second connecting electrode. In an embodiment, conductive particles are provided between the second connecting electrode and the first connecting electrode. In an embodiment, the first connecting electrodes and the light-emitting devices are connected by a connecting structure. In an embodiment, the connecting structure is provided between the first connecting electrode and the second connecting electrode, and/or, the connecting structure is provided on a sidewall of the first connecting electrode and a sidewall of the second connecting electrode.

In a second aspect, a display apparatus is provided. In an embodiment, the display apparatus includes the display panel described in the first aspect.

In a third aspect, a method for manufacturing a display panel described in the first aspect is provided. In an embodiment, the method includes: providing the substrate; manufacturing the first connecting electrode on the substrate; providing the light-emitting device including at least one second connecting electrode; providing curing reaction participants in which conductive particles are dispersed; aligning the first connecting electrode with the second connecting electrode, wherein at least part of the curing reaction participants is located between the first connecting electrode and the second connecting electrode after alignment; and laminating the light-emitting device with the substrate, so that the curing reaction participants between the first connecting electrode and the second connecting electrode forms the connecting structure. In an embodiment, conductive particles are provided between the second connecting electrode and the first connecting electrode; and the first connecting electrode and the light-emitting device are connected by a connecting structure; the connecting structure is provided between the first connecting electrode and the second connecting electrode, and/or, provided on a sidewall of the first connecting electrode and a sidewall of the second connecting electrode.

### BRIEF DESCRIPTION OF DRAWINGS

In order to more clearly illustrate technical solutions of embodiments of the present disclosure, the accompanying drawings used in the embodiments are briefly described below. The drawings described below are merely some of the embodiments of the present disclosure. Based on these drawings, those skilled in the art can obtain other drawings.

FIG. 1 is a schematic diagram of a display panel according to some embodiments of the present disclosure.

FIG. 2 is a schematic diagram of a display panel according to some embodiments of the present disclosure:

FIG. 3 is a schematic diagram of a display panel according to some embodiments of the present disclosure;

FIG. 4 is a schematic diagram of a display panel according to some embodiments of the present disclosure;

FIG. 5 is a schematic diagram of a display panel according to some embodiments of the present disclosure;

FIG. 6 is a schematic diagram of a display panel according to some embodiments of the present disclosure;

FIG. 7 is a schematic diagram of a display panel according to some embodiments of the present disclosure;

FIG. 8 is a schematic diagram of a display panel according to some embodiments of the present disclosure;

FIG. 9 is a schematic diagram of a display panel according to one embodiment of the present disclosure:

FIG. 10 is a schematic diagram of a display panel according to some embodiments of the present disclosure;

FIG. 11 is a schematic diagram of a display panel according to some embodiments of the present disclosure;

FIG. 12 is a schematic diagram of a display panel according to some embodiments of the present disclosure:

FIG. 13 is a schematic diagram of a display panel according to some embodiments of the present disclosure;

FIG. 14 is a schematic diagram of a display apparatus according to some embodiments of the present disclosure;

FIG. 15 is a schematic diagram of a method for manufacturing a display panel according to some embodiments of the present disclosure;

FIG. 16 is a schematic diagram of a method for manufacturing a display panel according to some embodiments of the present disclosure;

FIG. 17 is a schematic diagram of a method for manufacturing a display panel according to some embodiments of the present disclosure;

FIG. 18 is a schematic diagram of a method for manufacturing a display panel according to some embodiments of the present disclosure;

FIG. 19 is a schematic diagram of a method for manufacturing a display panel according to some embodiments of the present disclosure;

FIG. 20 is a schematic diagram of a method for manufacturing a display panel according to some embodiments of the present disclosure;

FIG. 21 is a schematic diagram of a method for manufacturing a display panel according to some embodiments of the present disclosure;

FIG. 22 is a schematic diagram of a method for manufacturing a display panel according to some embodiments of the present disclosure;

FIG. 23 is a schematic diagram of a method for manufacturing a display panel according to some embodiments of the present disclosure:

FIG. 24 is a schematic diagram of a method for manufacturing a display panel according to some embodiments of the present disclosure:

FIG. 25 is a schematic diagram of a method for manufacturing a display panel according to some embodiments of the present disclosure; and

FIG. 26 is a schematic diagram of a method for manufacturing a display panel according to some embodiments of the present disclosure.

### DESCRIPTION OF EMBODIMENTS

In order to better understand technical solutions of the present disclosure, the embodiments of the present disclosure are described in detail referring to the drawings.

It should be clear that the described embodiments are merely part of the embodiments of the present disclosure rather than all of the embodiments. All other embodiments obtained by those skilled in the art without paying creative labor shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there can be three relations, e.g., A and/or B can indicate only A, both A and B. and only B. In addition, the symbol “/” in the context generally indicates that the relation between the objects in front and at the back of “/” is an “or” relationship.

It should be understood that the terms ‘basically’, ‘approximately’, ‘about’, ‘generally’ and ‘substantially’ described in claims and embodiments of the present disclosure refer to a substantially approved value, rather than an exact value, within a reasonable process operation range or tolerance range.

It should be understood that although the terms ‘first’, ‘second’ and ‘third’ can be used in the present disclosure to describe connecting electrodes, these connecting electrodes should not be limited to these terms. These terms are used only to distinguish the connecting electrodes from each other. For example, without departing from the scope of the embodiments of the present disclosure, a first connecting electrode can also be referred to as a second connecting electrode. Similarly, the second connecting electrode can also be referred to as the first connecting electrode.

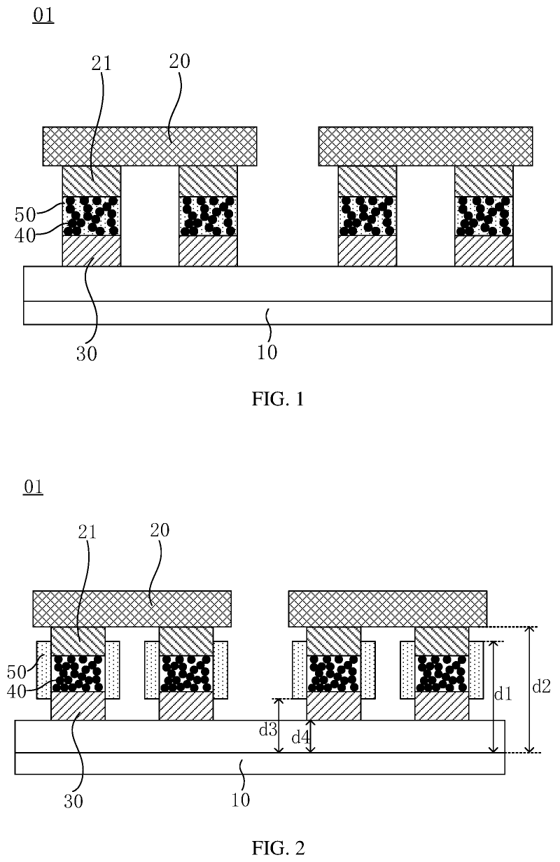

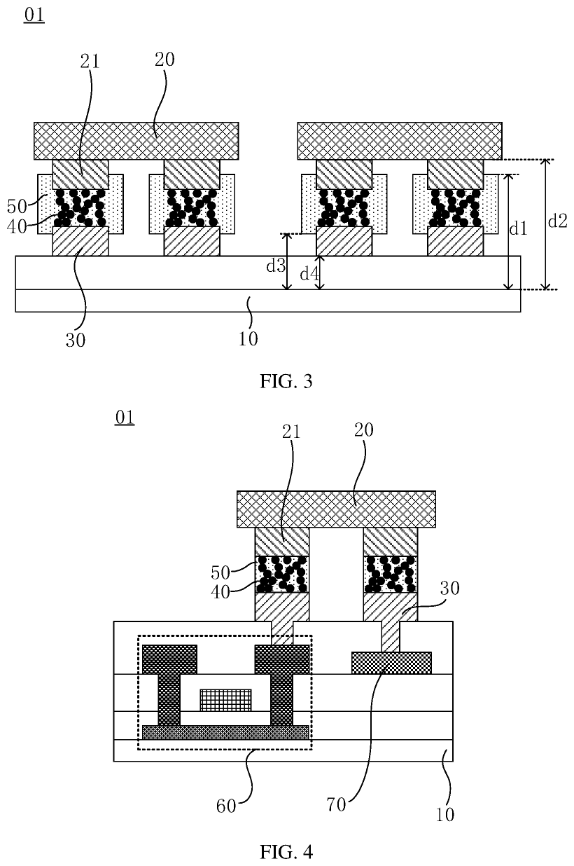

FIG. 1 is a schematic diagram of a display panel according to some embodiments of the present disclosure, FIG. 2 is a schematic diagram of a display panel according to some embodiments of the present disclosure, and FIG. 3 is a schematic diagram of a display panel according to some embodiments of the present disclosure.

As shown in FIG. 1 to FIG. 3, a display panel 01 according to embodiments of the present disclosure includes a substrate 10 and a light-emitting device 20 provided on a side of the substrate 10. In one application scenario of the present disclosure, the light-emitting device 20 is disposed on a side of the substrate 10 to emit light for display.

A first connecting electrode 30 is disposed on a side of the substrate 10. The first connecting electrode 30 is configured to electrically connect to the light-emitting device 20 so as to transmit the received signal to the light-emitting device 20.

The light-emitting device 20 includes at least one second connecting electrode 21, multiple conductive particles 40 are disposed between the second connecting electrode 21 and the first connecting electrode 30. That is, the second connecting electrode 21 and the first connecting electrode 30 are electrically connected by multiple conductive particles 40 located between the second connecting electrode 21 and the first connecting electrode 30, thereby achieving an electrical connection between the light-emitting device 20 and the first connecting electrode 30.

In addition, the display panel 01 further includes a connecting structure 50. The first connection electrode 30 and the light-emitting device 20 are connected by the connecting structure 50. That is, the electrical connection between the first connecting electrode 30 and the light-emitting device 20 is achieved by the conductive particles 40 located between the first connecting electrode 30 and the second connecting electrode 21, and a fixed connection between the first connecting electrode 30 and the light-emitting device is achieved by the connecting structure 50.

In some embodiments of the present disclosure, the connecting structure 50 is provided between the first connecting electrode 30 and the second connecting electrode 21, and/or, the connecting structure 50 is provided on a sidewall of the first connecting electrode 30 and a sidewall of the second connecting electrode 21.

In some embodiments of the present disclosure, as shown in FIG. 1, a connecting structure 50 is disposed between the first connecting electrode 30 and the second connecting electrode 21. That is, multiple conductive particles 40 that cause the first connecting electrode 30 to be electrically connected to the light-emitting device 20 are disposed between the first connecting electrode 30 and the second connecting electrode 21, and the connecting structure 50 that causes the first connection electrode 30 to be fixedly connected to the light-emitting device 20 is disposed between the first connection electrode 30 and the second connection electrode 21.

In some embodiments of the present disclosure, as shown in FIG. 2, a connecting structure 50 is provided on a sidewall of the first connecting electrode 30 and a sidewall of the second connecting electrode 21, that is, multiple conductive particles 40 that cause the first connecting electrode 30 to be electrically connected to the light-emitting device 20 are disposed between the first connecting electrode 30 and the second connecting electrode 21, and the connecting structure 50 that causes the first connection electrode 30 to be fixedly connected to the light-emitting device 20 is provided on the sidewall of the first connecting electrode 30 and the sidewall of the second connecting electrode 21.

In some embodiments of the present disclosure, as shown in FIG. 3, a connecting structure 50 is provided between the first connecting electrode 30 and the second connecting electrode 21, and is provided on the sidewall of the first connecting electrode 30 and the sidewall of the second connecting electrode 21, that is, multiple conductive particles 40 that cause the first connecting electrode 30 to be electrically connected to the light-emitting device 20 are disposed between the first connecting electrode 30 and the second connecting electrode 21, and the connecting structure 50 that causes the first connection electrode 30 to be fixedly connected to the light-emitting device 20 is disposed between the first connecting electrode 30 and the second connecting electrode 21, but also disposed on the sidewall of the first connecting electrode 30 and the sidewall of the second connecting electrode 21.

FIG. 4 is a schematic diagram of a display panel according to some embodiments of the present disclosure.

In some embodiments of the present disclosure, as shown in FIG. 4, a pixel circuit 60 and a signal line 70 can provided on a side of a substrate 10 providing the light-emitting device 20. A first connecting electrode 30 is electrically connected to the pixel circuit 60 to receive voltage signals, current signals, and the like formed by the pixel circuit 60; and/or, the first connecting electrode 30 is electrically connected to the signal line 70 to receive voltage signals, current signals, and the like transmitted by the signal line 70. The first connecting electrode 30 electrically connected to the pixel circuit 60 is configured to transmit a signal output by the pixel circuit 60 to one second connecting electrode 21 of the light-emitting device 20. The first connecting electrode 30 electrically connected to the signal line 70 is configured to transmit a signal transmitted by the signal line to one second connecting electrode 21 of the light-emitting device 20.

For example, as shown in FIG. 4, the light-emitting device 20 includes two second connecting electrodes 21 which correspond to the positive electrode and negative electrode of the light-emitting device 20 respectively. The two second connecting electrodes 21 of the light-emitting device 20 are electrically connected to different first connecting electrodes 30 respectively. In the first connecting electrodes 30 electrically connected to the two second connecting electrodes 21 respectively, one of first connecting electrodes 30 can be electrically connected to the pixel circuit 60, and the other of first connecting electrodes 30 can be electrically connected to the signal line 70.

In technical solutions of the present disclosure, the electrical connection between the second connecting electrode 21 in the light-emitting device 20 and the first connecting electrode 30 disposed on the substrate 10 is achieved by conductive particles 40 provided between them, avoiding the problem of heat-burn due to a larger electrical resistivity difference between the second connecting electrode 21 and the first connecting electrode 30. Moreover, a firmer fixed connection between the first connecting electrode 30 and the second connecting electrode 21 is achieved by the connecting structure 50.

In some embodiments of the present disclosure, the connecting structure 50 is a product of a curing reaction. That is, the connecting structure 50 can be formed by the curing reaction. When the light-emitting device 20 is assembled, curing reaction participants can be provided between the first connecting electrode 30 and the second connecting electrode 21. The connecting structure 50 that connects the first connecting electrode 30 and the second connecting electrode 21 is formed by a curing reaction of at least one of the curing reaction participants. The present disclosure provides a new method of assembling the light-emitting device 20, which is simple and easy to implement. Moreover, the use of high temperature, high voltage, and the like are not required, thereby protecting the performance of the light-emitting device 20.

In some embodiments of the present disclosure, the connecting structure 50 is formed by a curing reaction of a self-curing reactant which can be referred to as the curing reaction participant. That is, the self-curing reactant is provided between the first connecting electrode 30 and the second connecting electrode 21, and the connecting structure 50 that connects the first connecting electrode 30 and the second connecting electrode 21 is formed by a curing reaction of the self-curing reactant.

The self-curing reactant can be a self-curing epoxy.

In some embodiments of the present disclosure, the curing reactants are catalyzed by a curing agent to form the connecting structure 50. The curing agent and the curing reactant can be both referred to as the curing reaction participant. That is, the curing agent and the curing reactant are provided between the first connecting electrode 30 and the second connecting electrode 21, and the curing reactants was catalyzed by the curing agent to have a curing reaction, to form the connecting structure 50 that connects the first connecting electrode 30 and the second connecting electrode 21.

The curing reactant is an epoxy curing reactant, and the curing agent is an aliphatic amine curing agent.

In some embodiments of the present disclosure, as shown in FIG. 1, FIG. 3, and FIG. 4, at least part of the conductive particles 40 is dispersed in the connecting structure 50. That is, the conductive particles 40 can be doped in at least part of the curing reaction participants. After the connecting structure 50 is formed by the curing reaction, the conductive particles 40 are dispersed in the connecting structure 50.

In some embodiments of the present disclosure, the conductive particles 40 are doped in the self-curing reactant located between the first connecting electrode 30 and the second connecting electrode 21. When the light-emitting device 20 is assembled, by laminating the light-emitting device 20 and the substrate 10, part of the self-curing reactants between the first connecting electrode 30 and the second connecting electrode 21 overflow to perform a curing reaction, so that the connecting structure 50 located on the sidewall of the first connecting electrode 30 and the sidewall of the second connecting electrode 21 is formed. Meanwhile, the self-curing reactant remained between the first connecting electrode 30 and the second connecting electrode 21 performs a curing reaction to form the connecting structure 50 located between the first connecting electrode 30 and the second connecting electrode 21. Moreover, the amount of self-curing reactant remained between the first connecting electrode 30 and the second connecting electrode 21 is reduced, so that the electrical connection between the first connecting electrode 30 and the second connecting electrode 21 by conductive particles 40 is achieved.

In some embodiments of the present disclosure, the conductive particles 40 can be doped in a curing agent or a curing reactant located between the first connecting electrode 30 and the second connecting electrode 21. When the light-emitting device 20 is assembled, by laminating the light-emitting device 20 and the substrate 10, part of the curing agent and curing reactant between the first connecting electrode 30 and the second connecting electrode 21 overflow to perform a curing reaction, so that the connecting structure 50 located on the sidewall of the first connecting electrode 30 and the sidewall of the second connecting electrode 21 is formed. Meanwhile, the curing agent and curing reactant remained between the first connecting electrode 30 and the second connecting electrode 21 performs a curing reaction to form the connecting structure 50 located between the first connecting electrode 30 and the second connecting electrode 21. Moreover, the amount of curing agent and curing reactant remained between the first connecting electrode 30 and the second connecting electrode 21 is reduced, so that the electrical connection between the first connecting electrode 30 and the second connecting electrode 21 by conductive particles 40 is achieved.

In some embodiments of the present disclosure, the two connection types, i.e., electrical connection between the first connecting electrode 30 and the second connecting electrode 21 by the conductive particles 40, and a fixed connection by the connecting structure 50, can be achieved simultaneously in the curing reaction.

In some embodiments of the present disclosure, the light-emitting device 20 can be at least one of a micro light-emitting diode or a mini light-emitting diode. That is, multiple light-emitting devices 20 of the display panel 01 can each be a micro light-emitting diode, can also each be a mini light-emitting diode, or some light-emitting devices 20 of the display panel 01 are a micro light-emitting diode, and some light-emitting devices 20 of the display panel 01 are a mini light-emitting diode.

If the micro light-emitting diode or the mini light-emitting diode is assembled in the display panel 01, the connecting structure formed by the curing reaction can be used to achieve the assembly of micro diodes or the assembly of mini light-emitting diodes.

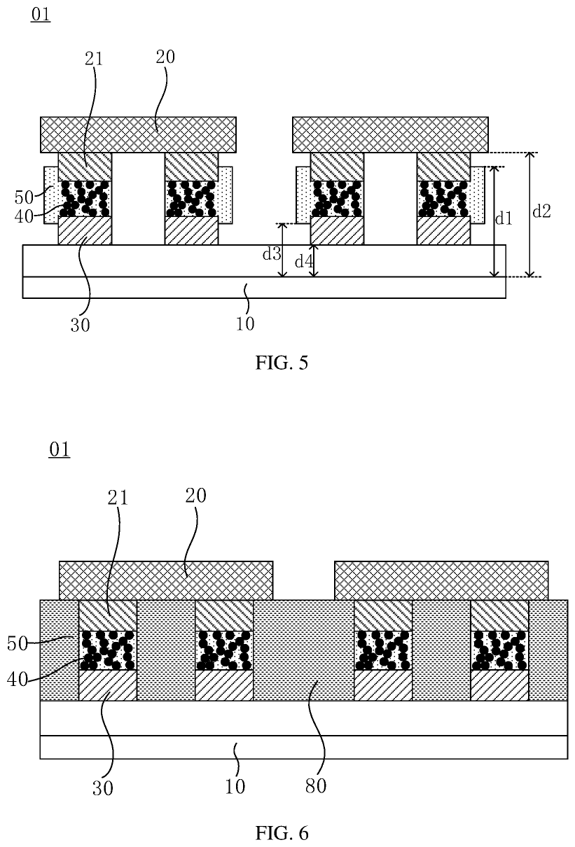

FIG. 5 is a schematic structural diagram of a display panel according to an embodiment of the disclosure.

In some embodiments of the present disclosure, as shown in FIG. 1 and FIG. 5, the light-emitting device 20 includes two second connecting electrodes 21 which can correspond to the positive and negative electrodes of the light-emitting device 20 respectively.

In the two second connecting electrodes 21 of a same light-emitting device 20, the opposite sidewalls of the two second connecting electrodes 21 are not provided with the connecting structure 50. For example, as shown in FIG. 1, none of the sidewalls of two second connecting electrodes 21 in the same light-emitting device 20 are provided with the connecting structure 50. For example, as shown in FIG. 5, the connecting structure 50 is provided on the sidewalls of the two second connecting electrodes 21 in the same light-emitting device 20, but the connecting structure 50 is not provided on a right sidewall of the second connecting electrode 21 on a left side, and the connecting structure 50 is not provided on a left sidewall of the second connecting electrode 21 on a right side.

In some embodiments of the present disclosure, when the curing reaction occurs to form the connecting structure 50, it is possible to avoid the presence of the curing reaction participant of the conductive particles 40 between the two second connecting electrodes 21 of a same light-emitting device 20, thereby effectively preventing the two second connecting electrodes 21 of a same light-emitting device 20 from electrically conduction.

In some embodiments of the present disclosure, as shown in FIG. 2, FIG. 3, and FIG. 5, when the connecting structure 50 is provided on the sidewall of the second connecting electrode 21, a distance between a top surface of the connecting structure 50 located on the sidewall of the second connecting electrode 21 away from the substrate 10 and the substrate 10 is d1, and a distance between a top surface of the second connecting electrode 21 away from substrate 10 and substrate 10 is d2, where d1<d2. That is, the connecting structure 50 provided on the sidewall of the second connecting electrode 21 does not extend to one end of the second connecting electrode 21 away from substrate 10, so that the connecting structure 50 is prevented from being in contact with a body of light-emitting device 20, for example, the connecting structure 50 is prevented from contacting an epitaxial part of the micro light-emitting diode or the mini light-emitting diode. Moreover, the conductive particles 40 incorporated in the connecting structure 50 on the sidewall of the second connecting electrode 21 are prevented from being electrically connected to the body of the light-emitting device 20, thereby achieving stability and accuracy of the signal received by the light-emitting device 20.

In some embodiments of the present disclosure, as shown in FIG. 2, FIG. 3, and FIG. 5, when the connecting structure 50 is provided on the sidewall of the first connecting electrode 30, a distance between a top surface of the connecting structure 50 located on the sidewall of the first connecting electrode 30 adjacent to the substrate 10 and the substrate 10 is d3, and a distance between a top surface of the first connecting electrode 30 adjacent to the substrate 10 and the substrate 10 is d4, where d3>d4. That is, the connecting structure 50 provided on the sidewall of the first connecting electrode 30 does not extend to one end of the first connecting electrode 30 adjacent to the substrate 10, so that the connecting structure 50 is prevented from contacting the body of light-emitting device 20, for example, the connecting structure 50 is prevented from contacting the layer on substrate 10. Moreover, the conductive particles 40 incorporated in the connecting structure 50 on the sidewall of the first connecting electrode 30 are prevented from contacting the conductive layer on the substrate 10, thereby achieving stability and accuracy of the signal transmitted by the first connecting electrode 30.

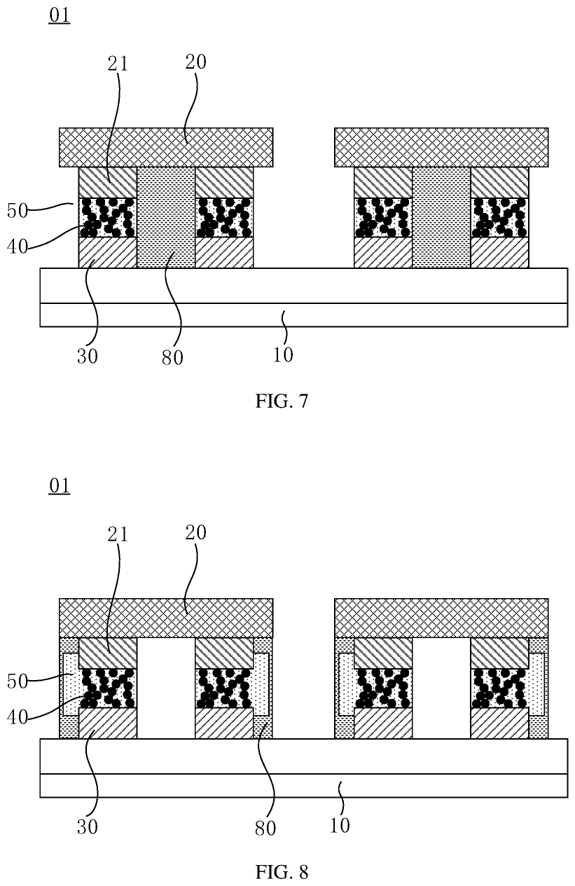

FIG. 6 is a schematic diagram of a display panel according to some embodiments of the present disclosure, FIG. 7 is a schematic diagram of a display panel according to some embodiments of the present disclosure, and FIG. 8 is a schematic diagram of a display panel according to some embodiments of the present disclosure.

In some embodiments of the present disclosure, as shown in FIGS. 6-8, insulating glue 80 is disposed at a periphery of the second connecting electrode 21. The insulating glue 80 is fixed to both the sidewall of the first connecting electrode 30 and the sidewall of the second connecting electrode 21.

In some embodiments of the present disclosure, the fixed connection between the first connecting electrode 30 and the second connecting electrode 21 can not only be achieved by the connecting structure 50, but also be achieved by the insulating glue 80.

The insulating glue 80 can be a self-curing reactant or a curing reactant having a solid structure. The process of the curing reaction can release energy, the self-curing reactant or curing reactant of the sidewall of the second connecting electrode 21 and the first connecting electrode 30 is heated to become a solid structure, that is, the insulating glue 80 is formed.

By controlling a setting position of the conductive particles 40 before the curing reaction, an extrusion force when assembling the light-emitting device 20, and the extrusion time when assembling the light-emitting device 20, and the like, the presence of conductive particles 40 that can form conductive paths in the insulating glue 80 can be avoided.

When the light-emitting device 20 is a micro light-emitting diode or a mini light-emitting diode, in an assembling process of the micro light-emitting diode or mini light-emitting diode, the insulating glue 80 can fixedly connect the epitaxial part of the micro light-emitting diode or mini light-emitting diode to the layer on the substrate 10.

In some embodiments of the present disclosure, as shown in FIG. 6 and FIG. 7, the light-emitting device 20 includes two second connecting electrodes 21. The insulating glue 80 is provided between two second connecting electrodes 21 of a same light-emitting device 20. In this way, the insulating glue 80 is used to fixedly connect the light-emitting device 20.

In some embodiments of the present disclosure, as shown in FIG. 7, the insulating glue 80 can be provided between the two second connecting electrodes 21 of a same light-emitting device 20 but not provided at other positions, so that an excessive area of the insulating glue 80 is prevented from affecting heat dissipation of the light-emitting device 20.

In some embodiments of the present disclosure, as shown in FIG. 7 and FIG. 8, at least part of a region between adjacent light-emitting devices 20 is not provided with the insulating glue 80, so that excessive amount of the insulating glue 80 is prevented from affecting heat dissipation of the light-emitting device 20.

In some embodiments of the present disclosure, as shown in FIG. 8, in the region between adjacent light-emitting devices 20, the sidewall of the first connecting electrode 30 and the sidewall position of the second connecting electrode 21 comprise insulating glue 80 and other regions do not comprise the insulating glue 80. In addition, the insulating glue 80 is not disposed between the two second connecting electrodes 21 of a same light-emitting device 20, which can further reduce the influence of the insulating glue 80 on heat dissipation of the light-emitting device 20.

As shown in FIG. 8, the opposite sidewalls of the two second connecting electrodes 21 in the same light-emitting device 20 do not comprise the connecting structure 50 but other positions of the sidewall are provided with the connecting structure 50, and correspondingly, the sidewall of the second connecting electrode 21 providing the connecting structure 50 provides the insulating glue 80 which can be formed by the heat dissipated when the connecting structure 50 on the sidewall of the second connecting electrode 21 is formed.

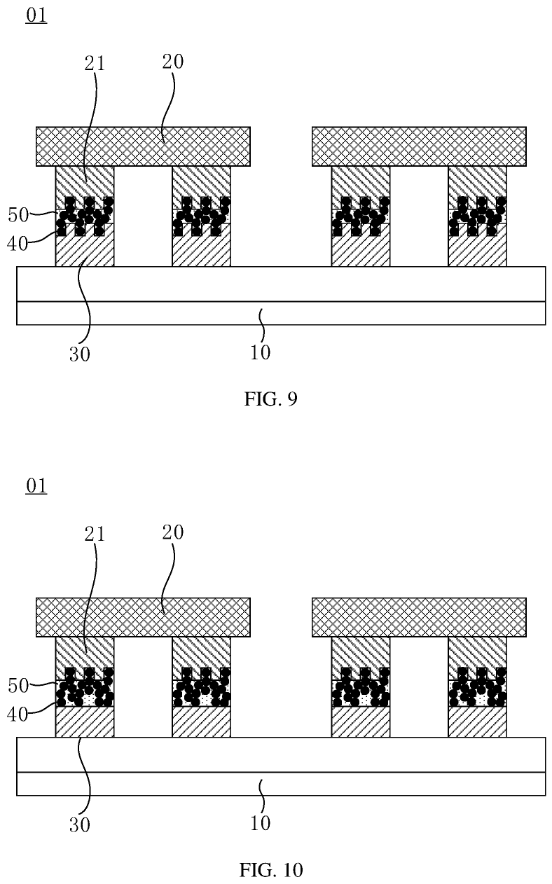

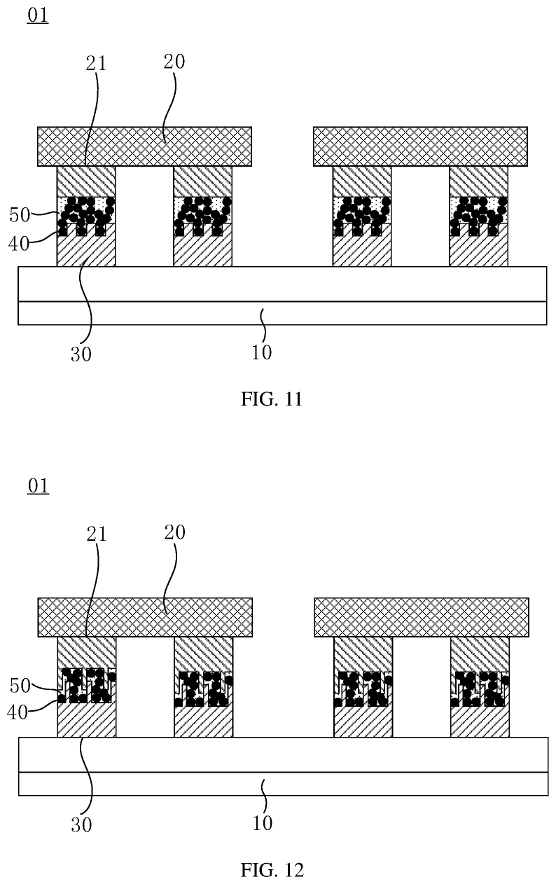

FIG. 9 is a schematic diagram of a display panel according to one embodiment of the present disclosure, FIG. 10 is a schematic diagram of a display panel according to some embodiments of the present disclosure, and FIG. 11 is a schematic diagram of a display panel according to some embodiments of the present disclosure.

In some embodiments of the present disclosure, as shown in FIGS. 9-11, a surface of the second connecting electrode 21 facing the first connecting electrode 30 is a concavo-convex structure, and/or, a surface of the first connecting electrode 30 facing the second connecting electrode 21 is a concavo-convex structure.

Whether the concavo-convex structure is provided on the first connecting electrode 30 or on the second connecting electrode 21 can be determined according to the setting position of the curing reaction participant. That is, the structure surface provided with the curing reaction participant can be provided as a concavo-convex structure to increase a contact area of the curing reaction participant and the first connecting electrode 30 and/or the second connecting electrode 21, thereby increasing contact stability.

For example, the self-curing reactant is provided on a side of the second connecting electrode 21 facing the first connecting electrode 30, so that the surface of the second connecting electrode 21 facing the first connecting electrode 30 is provided as a concavo-convex structure, as shown in FIG. 10.

For example, the self-curing reactant is provided on a side of the first connecting electrode 30 facing the second connecting electrode 21, so that the surface of the first connecting electrode 30 facing the second connecting electrode 21 is provided as a concavo-convex structure, as shown in FIG. 11.

For example, one of the curing agent and the curing reactant is provided on a side of the second connecting electrode 21 facing the first connecting electrode 30, and the other of the curing agent and the curing reactant is provided on a side of the first connecting electrode 30 facing the second connecting electrode 21, so that as shown in FIG. 9, the surface of the second connecting electrode 21 facing the first connecting electrode 30 is provided as a concave-convex structure, and the surface of the first connecting electrode 30 facing the second connecting electrode 21 is provided as a concave-convex structure.

When the connecting structure 50 is provided between the first connecting electrode 30 and the second connecting electrode 21, the surface of the first connecting electrode 30 and/or the second connecting electrode 21 are provided as a concavo-convex structure, so that the contact area of the connecting structure 50 and the first connecting electrode 30 and/or the second connecting electrode 21 can be increased, thereby having a high stability of the fixed connection of the light-emitting device by the connecting structure 50.

In some embodiments of the present disclosure, as shown in FIG. 9, the surface of the first connecting electrode 30 facing the second connecting electrode 21 is a concavo-convex structure, and the surface of the second connecting electrode 21 facing the first connecting electrode 30 is a concavo-convex structure.

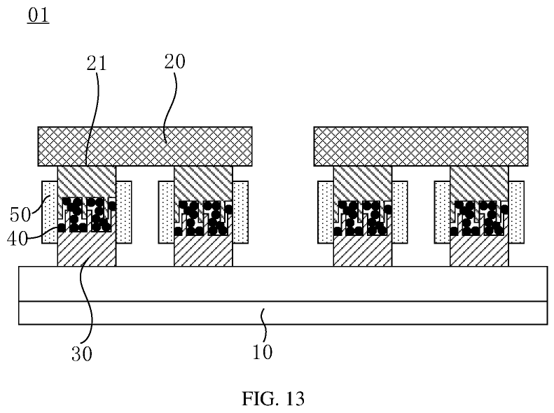

FIG. 12 is a schematic diagram of a display panel according to some embodiments of the present disclosure, and FIG. 13 is a schematic diagram of a display panel according to some embodiments of the present disclosure.

As shown in FIG. 12 and FIG. 13, when the surface of the second connecting electrode 21 facing the first connecting electrode 30 is a concavo-convex structure, and when the surface of the first connecting electrode 30 facing the second connecting electrode 21 is a concavo-convex structure, protrusions of the concave-convex structure of the second connecting electrode 21 can extend at least partially into grooves of the concave-convex structure in the first connecting electrode 30, and protrusions of the concave-convex structure of the first connecting electrode 30 can extend at least partially into grooves of the concave-convex structures of the second connecting electrode 21.

The connecting structure 50 can be provided between the first connecting electrode 30 and the second connecting electrode 21 as shown in FIG. 12, and the connecting structure 50 can also be provided on the sidewall of the first connecting electrode 30 and the sidewall of the second connecting electrode 21 as shown in FIG. 13.

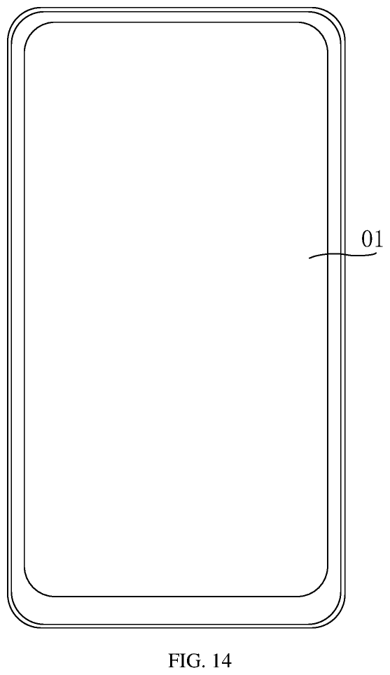

FIG. 14 is a schematic diagram of a display apparatus according to some embodiments of the present disclosure.

As shown in FIG. 14, a display apparatus provided by embodiments of the present disclosure includes a display panel as provided in any one of the embodiments described above. The display apparatus provided by embodiments of the present disclosure can be a mobile phone, a computer, a television, or the like.

In the display apparatus provided by the embodiments of the present disclosure, the electrical connection between the second connecting electrode 21 of the light-emitting device 20 and the first connecting electrode 30 provided on the substrate 10 is achieved by the conductive particles 40 provided between them, avoiding the problem of heat-burn due to a larger electrical resistivity difference between the second connecting electrode 21 and the first connecting electrode 30. Furthermore, a more secure fixed connection is achieved by the connecting structure 50 between the first connecting electrode 30 and the second connecting electrode 21. Accordingly, the display apparatus provided by the embodiments of the present disclosure has reliable light-emitting performance.

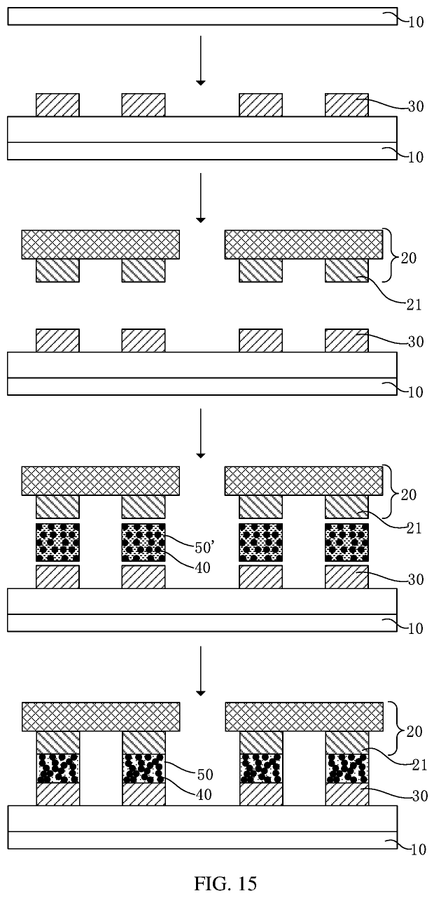

FIG. 15 is a schematic diagram of a method for manufacturing a display panel according to some embodiments of the present disclosure.

The present disclosure further provides a method for manufacturing a display panel, which is used for manufacturing the display panel mentioned in any one of the embodiments described above. As shown in FIG. 15, an embodiment of the method includes following steps:

providing a substrate 10;

manufacturing a first connecting electrode 30 on the substrate 10:

providing a light-emitting device 20 including at least one second connecting electrode 21:

providing curing reaction participants 50′ in which multiple conductive particles 40 are dispersed:

aligning the first connecting electrode 30 with the second connecting electrode 21, at least part of the curing reaction participant 50′ being located between the first connecting electrode 30 and the second connecting electrode 21 after alignment; and

laminating the light-emitting device 20 with the substrate 10, so that the curing reaction participant 50′ between the first connecting electrode 30 and the second connecting electrode 21 forms a connecting structure 50.

Multiple conductive particles 40 are provided between the second connecting electrode 21 and the first connecting electrode 30. The second connecting electrode 21 and the first connecting electrode 30 are connected by the connecting structure 50. As shown in FIG. 1 to FIG. 3, the connecting structure 50 is provided between the first connecting electrode 30 and the second connecting electrode 21, and/or, the connecting structure 50 is provided on a sidewall of the first connecting electrode 30 and a sidewall of the second connecting electrode 21.

In the method according to the embodiments of the present disclosure, by providing the curing reaction participants between the first connecting electrode 30 and the second connecting electrode 21, at least one of the curing reaction participants will undergo a curing reaction to form the connecting structure 50 that causes the first connecting electrode 30 to connect to the second connecting electrode 21, so that a more secure fixed connection between the first connecting electrode 30 and the second connecting electrode 21 is achieved through the connecting structure 50. When the curing reaction occurs, conductive particles 40 doped in the curing reaction participants achieves an electrical connection between the second connecting electrode 21 and the first connecting electrode 30, w % bile avoiding the problem of heat-burn due to a larger electrical resistivity difference between the second connecting electrode 21 and the first connecting electrode 30. The method provided by the embodiments of the present disclosure provides a new manner of assembling the light-emitting device 20, which is simple and easy to implement. Moreover, the operations of high temperature, high voltage, and the like are not required, thereby protecting the performance of the light-emitting device 20.

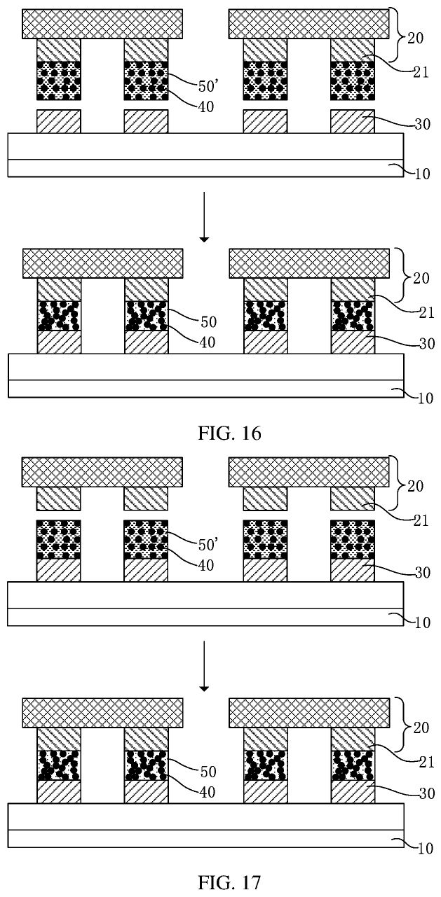

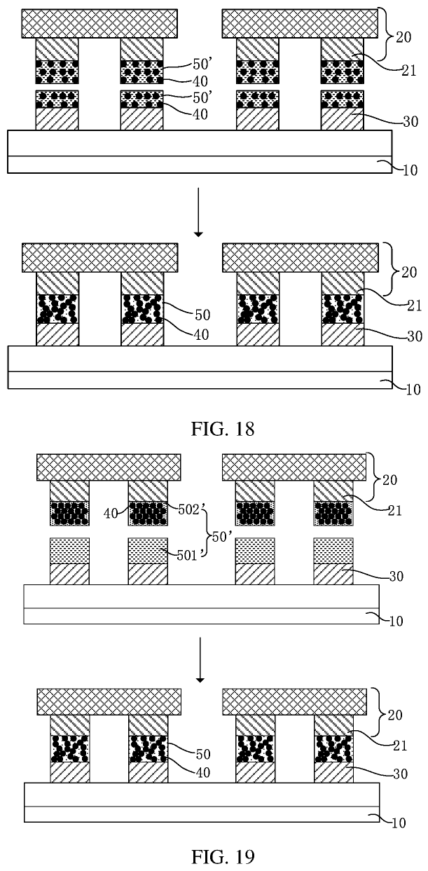

FIG. 16 is a schematic diagram of a method for manufacturing a display panel according to some embodiments of the present disclosure, FIG. 17 is a schematic diagram of a method for manufacturing a display panel according to some embodiments of the present disclosure, and FIG. 18 is a schematic diagram of a method for manufacturing a display panel according to some embodiments of the present disclosure.

In some embodiments of the present disclosure, the curing reaction participants 50′ include a self-curing reactant, and the conductive particles 40 are dispersed in the self-curing reactant 50′.

In some embodiments of the present disclosure, as shown in FIG. 16, the method further includes:

at least part of the self-curing reactant is provided on one end of the second connecting electrode 21 facing the first connecting electrode 30, without connecting to the self-curing reactant on the adjacent second connecting electrode 21.

In some embodiments of the present disclosure, as shown in FIG. 17, the method further includes:

at least part of the self-curing reactant is provided on one end of the first connecting electrode 30 facing the second connecting electrode 21, without connecting to the self-curing reactant on the adjacent first connecting electrode 30.

In some embodiments of the present disclosure, as shown in FIG. 18, the method further includes:

at least part of the self-curing reactant is provided on one end of the second connecting electrode 21 facing the first connecting electrode 30, and at least part of the self-curing reactant is provided on one end of the first connecting electrode 30 facing the second connecting electrode 21, without connecting to the self-curing reactant on the adjacent second connecting electrode 21 and without connecting to the self-curing reactant on the adjacent first connecting electrode 30.

In the method provided by the embodiments of the present disclosure, when the light-emitting device 20 and the substrate 10 are laminated, a suitable reaction environment is provided so that the self-curing reactant performs a curing reaction to form a connecting structure 50 that causes the first connecting electrode 30 to be connected to the second connecting electrode 21. For example, the temperature of the environment at which the self-curing reactant is provided is so that the self-curing reactant performs a curing reaction to form a connecting structure 50.

Meanwhile, when the light-emitting device 20 and the substrate 10 are laminated, the amount of the self-curing reactant located between the first connecting electrode 30 and the second connecting electrode 21 is reduced, so that it is possible for the conductive particles 40 to form a conductive path to electrically connect the first connecting electrode 30 and the second connecting electrode 21.

In addition, the self-curing reactants on adjacent second connecting electrodes 21 are not connected, so that the risk of the electrical connection between adjacent second connecting electrodes 21 by the conductive particles 40 doped in the self-curing reactant and/or the conductive particles 40 in the connecting structure 50 formed by the self-curing reactant is avoided. The self-curing reactants on adjacent first connecting electrodes 30 are not connected, so that the risk of the electrical connection between adjacent first connecting electrodes 30 by the conductive particles 40 doped in the self-curing reactant and/or the conductive particles 40 in the connecting structure 50 formed by the self-curing reactant is avoided.

In some embodiments of the present disclosure, the self-curing reactant can be a self-curing epoxy.

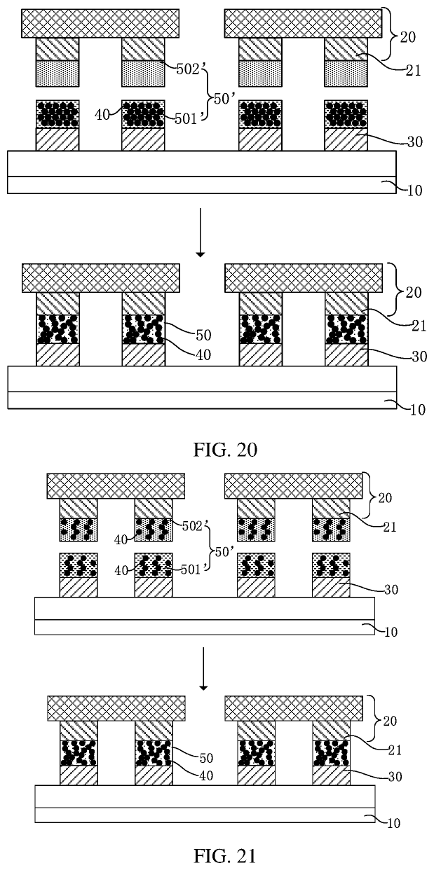

FIG. 19 is a schematic diagram of a method for manufacturing a display panel according to some embodiments of the present disclosure, FIG. 20 is a schematic diagram of a method for manufacturing a display panel according to some embodiments of the present disclosure, and FIG. 21 is a schematic diagram of a method for manufacturing a display panel according to some embodiments of the present disclosure.

In some embodiments of the present disclosure, as shown in FIGS. 19-21, the curing reaction participant 50′ includes a curing reactant 501′ and a curing agent 502′, and conductive particles 40 are dispersed in the curing agent 502′, and/or the conductive particles 40 are dispersed in the curing reactant 501′. For example, as shown in FIG. 19, the conductive particles 40 are dispersed in the curing agent 502′; as shown in FIG. 20, the conductive particles 40 are dispersed in the curing reactant 501′; as shown in FIG. 21, part of conductive particles 40 are dispersed in the curing agent 502′ and part of conductive particles 40 are dispersed in the curing reactant 501.

As shown in FIG. 19 to FIG. 21, laminating light-emitting device 20 and substrate 10 to form the connecting structure 50 by the curing reaction participant 50′ located between the first connecting electrode 30 and the second connecting electrode 21, includes:

the light-emitting device 20 and the substrate 10 are laminated, so that the curing reactant 501′ at least located between the first connection electrode 30 and the second connection electrode 21 is in contact with the curing agent 502′, and the curing reactant 501′ in contact with the curing agent 502 forms the connecting structure 50.

In the method provided by the embodiments of the present disclosure, when the light-emitting device 20 and the substrate 10 are laminated, the curing reactant 501′ is in contact with the curing agent 502′, and the curing agent 502′ catalyzes the curing reactant 501′ to perform a curing reaction so as to form the connecting structure 50 that causes the first connecting electrode 30 to connect to the second connecting electrode 21.

Meanwhile, when the light-emitting device 20 and the substrate 10 are laminated, the amount of the curing reactant 501′ and the curing agent 502′ located between the first connecting electrode 30 and the second connecting electrode 21 is reduced, so that it is possible for the conductive particles 40 to form a conductive path to electrically connect the first connecting electrode 30 and the second connecting electrode 21.

In some embodiments of the present disclosure, as shown in FIGS. 19 and 21, providing curing reaction participants 50′ in which multiple conductive particles are dispersed, includes:

the curing agent 502′ is provided on one end of the second connecting electrode 21 facing the first connecting electrode 30; and the conductive particles 40 are dispersed in the curing agent 502′ without connecting the curing agent 502′ of an adjacent second connecting electrode 21. The curing agents 502′ on adjacent second connecting electrodes 21 are not connected, so that the risk of the electrical connection between adjacent second connecting electrodes 21 by the conductive particles 40 doped in the curing agent 502′ and/or the conductive particles 40 in the connecting structure 50 formed by the self-curing reactant is avoided.

In addition, as shown in FIG. 19 and FIG. 21, this step further includes:

a curing reactant 501′ is provided, and at least part of curing reactant 501′ is provided on one end of the first connecting electrode 30 facing the second connecting electrode 21, that is, at least part of the curing agent 502′ is provided on the second connecting electrode 21 and located between the second connecting electrode 21 and the first connecting electrode 30, at least part of the curing reactant 501′ is provided on the first connecting electrode 30 and located between the first connecting electrode 30 and the second connecting electrode 21. Therefore, when the light-emitting device 20 and the substrate 10 are laminated, a curing reaction occurs after the curing agent 502′ and the curing reactant 501′ located between the first connecting electrode 30 and the second connecting electrode 21 are in contact with each other.

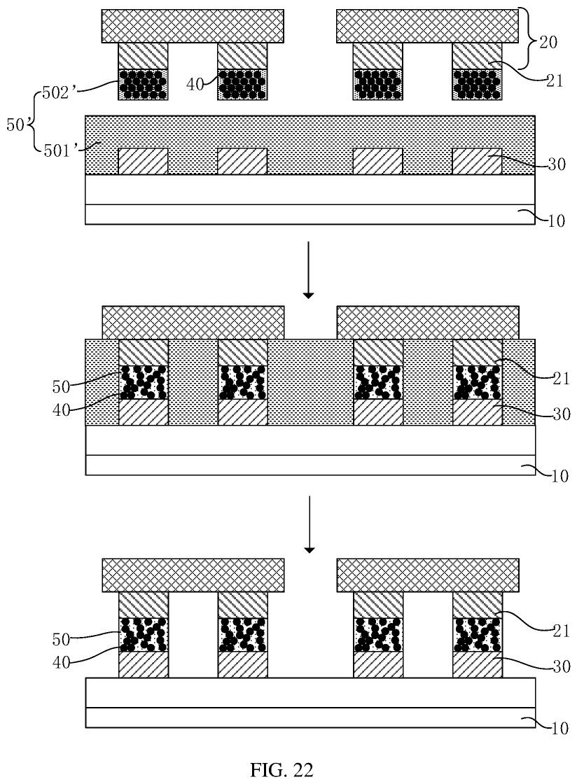

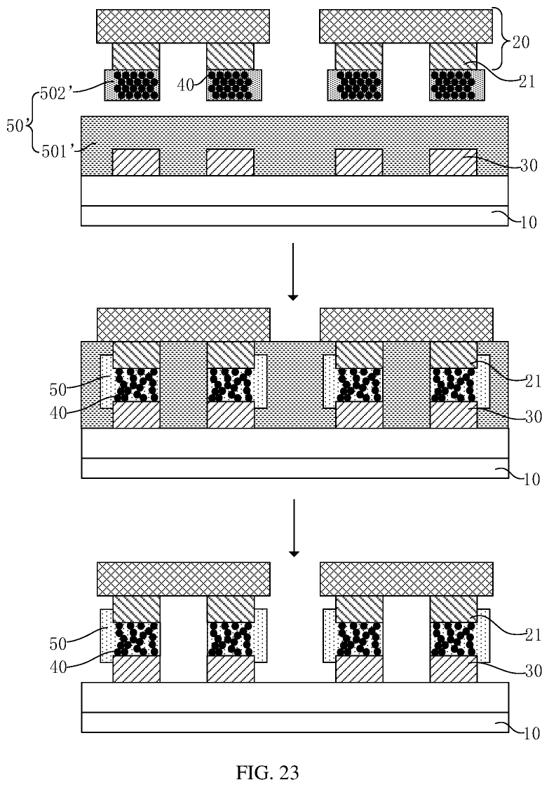

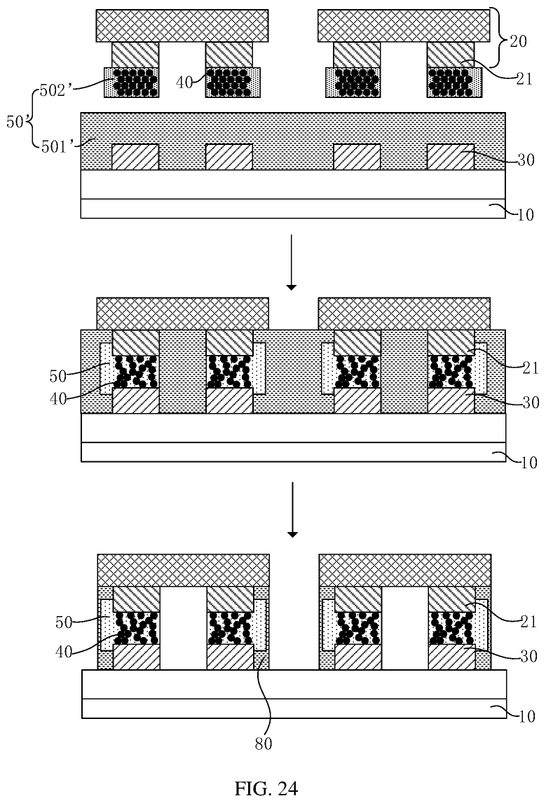

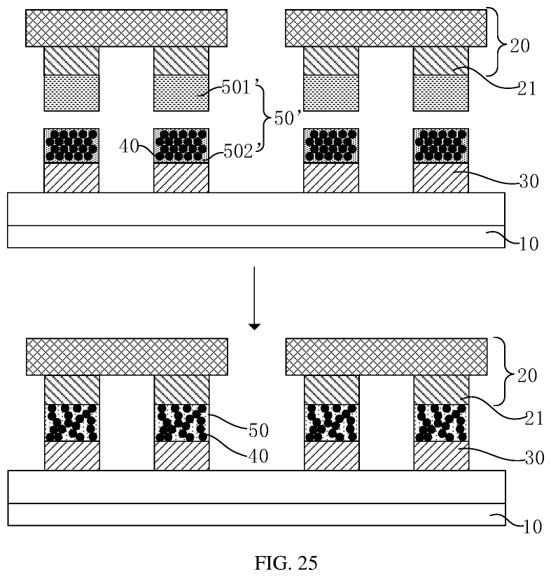

FIG. 22 is a schematic diagram of a method for manufacturing a display panel according to some embodiments of the present disclosure. FIG. 23 is a schematic diagram of a method for manufacturing a display panel according to some embodiments of the present disclosure, and FIG. 24 is a schematic diagram of a method for manufacturing a display panel according to some embodiments of the present disclosure.

In some embodiments of the present disclosure, as shown in FIG. 22 to FIG. 24, the providing at least part of the curing reactant 501′ on one end of the first connecting electrode 30 facing the second connecting electrode 21, includes: the curing reactant 501′ is provided to cover multiple first connecting electrodes 30, so that a more efficient connecting structure 50 can be formed.

In some embodiments of the present disclosure, the curing agent 502′ can protrude from the electrode on which it is provided, as shown in FIG. 23 and FIG. 24, when the curing agent 502′ is provided on the second connecting electrode 21, the curing agent 502′ protrudes from the second connecting electrode 21 to achieve that the sidewall of the first connecting electrode 30 and the sidewall of the second connecting electrode 21 both provide the connecting structure 50.

In addition, as shown in FIG. 22 to FIG. 24, when the light-emitting device 20 includes two second connecting electrodes 21, the protruding direction of the curing agent 502′ is a direction away from the region between the two second connecting electrodes 21, the conductive particles 40 in the curing agent 502′ are prevented from electrically conducting the two second connecting electrodes 21.

In some embodiments of the present disclosure, after the light-emitting device 20 and the substrate 10 are laminated to form the curing structure 50 by the curing reaction participants 501′ located between the first connecting electrode 30 and the second connecting electrode 21, the curing reactant 501′ in a non-solid state between adjacent light-emitting devices 20 is removed.

As shown in FIG. 24, when the heat generated by the curing reaction causes the state of part of the curing reactant 501′ adjacent to the second connecting electrode 21 and the first connecting electrode 30 to be a solid state, that is, when the insulating glue 80 is formed, the part of the insulating glue 80 can be retained, achieving a more secure fixed connection between the light-emitting device 20 and the first connecting electrode 30. Moreover, the other curing reactant 501′ is removed to facilitate heat dissipation of the light-emitting device 20.

FIG. 25 is a schematic diagram of a method for manufacturing a display panel according to some embodiments of the present disclosure.

In some embodiments of the present disclosure, as shown in FIG. 25, the providing the curing reaction participants 50′ in which conductive particles are dispersed, includes:

the curing agent 502′ is provided on one end of the first connecting electrode 30 facing the second connecting electrode 21; the conductive particles 40 are dispersed in the curing agent 502′ without connecting the curing agent of an adjacent first connecting electrode. The curing agents 502′ on adjacent first connecting electrodes 30 are not connected, so that the risk of the electrical connection between adjacent first connecting electrodes 30 by the conductive particles 40 doped in the curing agent 502′ and/or the conductive particles 40 in the connecting structure 50 formed by the self-curing reactant is avoided.

In addition, as shown in FIG. 25, this step further includes:

the curing reactant 501′ is provided on one end of the second connecting electrode 21 facing the first connecting electrode 30. That is, at least part of the curing agent 502′ is provided on the first connecting electrode 30 and located between the first connecting electrode 30 and the second connecting electrode 21, at least part of the curing reactant 501′ is provided on the second connecting electrode 21 and located between the second connecting electrode 21 and the first connecting electrode 30. Therefore, when the light-emitting device 20 and the substrate 10 are laminated, a curing reaction occurs after the curing agent 502′ and the curing reactant 501′ located between the first connecting electrode 30 and the second connecting electrode 21 are in contact with each other.

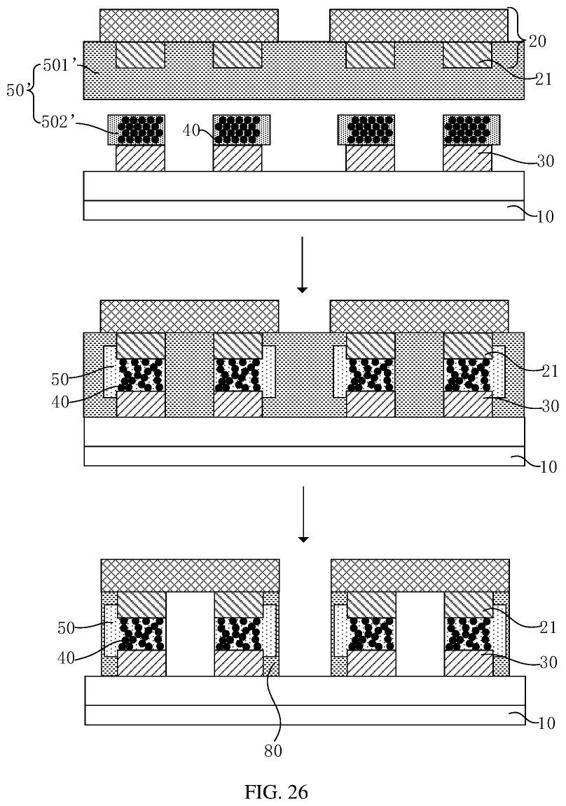

FIG. 26 is a schematic diagram of a method for manufacturing a display panel according to some embodiments of the present disclosure.

In some embodiments of the present disclosure, as shown in FIG. 26, the providing at least part of the curing reactant 501′ on one end of the second connecting electrode 21 facing the first connecting electrode 30, includes: the curing reactant 501′ is provided to cover multiple second connecting electrodes 21.

In some embodiments of the present disclosure, the curing agent 502′ can protrude from the electrode on which it is provided, as shown in FIG. 26, when the curing agent 502′ is provided on the first connecting electrode 30, the curing agent 502′ protrudes from the first connecting electrode 30 to achieve that the sidewall of the first connecting electrode 30 and the sidewall of the second connecting electrode 21 both provide the connecting structure 50.

In addition, as shown in FIG. 26, when the light-emitting device 20 includes two second connecting electrodes 21, the protruding direction of the curing agent 502′ is a direction away from the region between two first connecting electrodes 30 electrically connected to two second connecting electrodes 21, respectively, the conductive particles 40 in the curing agent 502′ are prevented from electrically conducting the two first connecting electrodes 30.

In the embodiments of the present disclosure, after the light-emitting device 20 and the substrate 10 are laminated to form the curing structure 50 by the curing reaction participants 501′ located between the first connecting electrode 30 and the second connecting electrode 21, the curing reactant 501′ in a non-solid state between adjacent light-emitting devices 20 is removed.

As shown in FIG. 26, when the heat generated by the curing reaction causes the state of part of the curing reactant 501′ adjacent to the second connecting electrode 21 and the first connecting electrode 30 to be a solid state, that is, when the insulating glue 80 is formed, the part of the insulating glue 80 can be retained, achieving a more secure fixed connection between the light-emitting device 20 and the first connecting electrode 30. Moreover, the other curing reactant 501′ is removed to facilitate heat dissipation of the light-emitting device 20.

When the light-emitting device 20 and the substrate 10 are laminated, the curing reaction participants between the first connecting electrode 30 and the second connecting electrode 21 partially overflows, so that the connecting structure 50 can include the part located at the sidewall of the first connecting electrode 30 and the part located at the sidewall of the second connecting electrode 21. Furthermore, when all of curing reaction participants between the first connecting electrode 30 and the second connecting electrode 21 overflow, the connecting structure 50 can be located on the sidewall of the first connecting electrode 30 and located on the sidewall of the second connecting electrode 21, while the connecting structure 50 may not include the part located between the first connecting electrode 30 and the second connecting electrode 21.

In addition, by controlling the amount of curing reaction participants between the first connecting electrode 30 and the second connecting electrode 21 and the force of laminating the light-emitting device 20 with the substrate 10, the connecting structure 50 can be only located between the first connecting electrode 30 and the second connecting electrode 21.

In some embodiments of the present disclosure, the curing reactant 501′ is an epoxy curing reactant. The curing agent 502′ is an aliphatic amine curing agent, such as tetraethylenepentamine (H₂NC₂H₄(NHC₂H₄)₃NH₂), polyethylene polyamine (H₂NC₂H₄(NHC₂H₄)ₙNH₂), dipropylenetriamine (H₂N(CH₂)₃NH(CH₂)₃NH₂).

The above are merely preferred embodiments of the present disclosure, which, as mentioned above, are not used to limit the present disclosure. Whatever within the principles of the present disclosure, including any modification, equivalent substitution, improvement, etc., shall fall into the protection scope of the present disclosure.

What is claimed is:

1. A display panel, comprising:
a substrate;
a first connecting electrode disposed on a side of the substrate;
a light-emitting device comprising at least one second connecting electrode; and
conductive particles disposed between the second connecting electrode and the first connecting electrode; and
wherein the first connecting electrodes and the light-emitting devices are connected by a connecting structure; wherein the connecting structure is disposed between the first connecting electrode and the second connecting electrode, and/or, the connecting structure is disposed on a sidewall of the first connecting electrode and a sidewall of the second connecting electrode.

2. The display panel according to claim 1, wherein the connecting structure is formed by a curing reaction.

3. The display panel according to claim 2, wherein at least portion of the conductive particles are dispersed in the connecting structure.

4. The display panel according to claim 2, wherein the light-emitting device is at least one of a micro light-emitting diode or a mini light-emitting diode.

5. The display panel according to claim 2, wherein a surface of the second connecting electrode facing the first connecting electrode is a second concavo-convex structure, or, a surface of the first connecting electrode facing the second connecting electrode is a first concavo-convex structure.

6. The display panel according to claim 2, wherein a surface of the second connecting electrode facing the first connecting electrode is a second concavo-convex structure, and a surface of the first connecting electrode facing the second connecting electrode is a first concavo-convex structure.

7. The display panel according to claim 6, wherein protrusions of the first concavo-convex structure of the first connecting electrode extend into grooves of the second concavo-convex structure of the second connecting electrode, and protrusions of the second concavo-convex structure of the second connecting electrode extends into grooves of the first concavo-convex structure of the first connecting electrode.

8. The display panel according to claim 2, wherein the light-emitting device comprises two second connecting electrodes; and
the connecting structure is not disposed on opposite sidewalls of the two second connecting electrodes of a same light-emitting device.

9. The display panel according to claim 2, wherein the connecting structure is disposed on a sidewall of the first connecting electrode and a sidewall of the second connecting electrode;
wherein, in the connecting structure provided on the sidewall of the second connecting electrode, a distance d1 between a top surface of the connecting structure away from the substrate and the substrate is smaller than a distance d2 between a top surface of the second connecting electrode away from the substrate and the substrate; and
wherein, in the connecting structure provided on the sidewall of the first connecting electrode, a distance d3 between the top surface of the connecting structure adjacent to the substrate and the substrate is greater than a distance d4 between the top surface of the first connecting electrode adjacent to the substrate and the substrate.

10. The display panel according to claim 2, wherein a periphery of the second connecting electrode comprises an insulating glue, and the insulating glue is fixed to both the sidewall of the first connecting electrode and the sidewall of the second connecting electrode.

11. The display panel according to claim 10, wherein the light-emitting device comprises two second connecting electrodes; and
wherein the insulating glue is provided between two second connecting electrodes of a same light-emitting device.

12. The display panel according to claim 10, wherein at least part of an area between adjacent light-emitting devices does not comprise the insulating glue.

13. A display apparatus, comprising a display panel, wherein the display panel comprises:
a substrate;
a first connecting electrode provided on a side of the substrate;
a light-emitting device comprising at least one second connecting electrode; and
conductive particles disposed between the second connecting electrode and the first connecting electrode; and
wherein the first connecting electrode and the light-emitting device are connected by a connecting structure; the connecting structure is disposed between the first connecting electrode and the second connecting electrode, and/or, the connecting structure is disposed on a sidewall of the first connecting electrode and a sidewall of the second connecting electrode.

14. A method for manufacturing a display panel, the display panel comprising:
a substrate;
a first connecting electrode provided on a side of the substrate;
a light-emitting device comprising at least one second connecting electrode; and
conductive particles disposed between the second connecting electrode and the first connecting electrode; and
wherein the first connecting electrode and the light-emitting device are connected by a connecting structure; the connecting structure is disposed between the first connecting electrode and the second connecting electrode, and/or, the connecting structure is disposed on a sidewall of the first connecting electrode and a sidewall of the second connecting electrode;
wherein the method comprises:
providing the substrate;
manufacturing the first connecting electrode on the substrate;
providing the light-emitting device comprising at least one second connecting electrode;
providing curing reaction participants in which conductive particles are dispersed;
aligning the first connecting electrode with the second connecting electrode, wherein at least part of the curing reaction participants is located between the first connecting electrode and the second connecting electrode after alignment; and
laminating the light-emitting device with the substrate, so that the curing reaction participants between the first connecting electrode and the second connecting electrode forms the connecting structure.

15. The method according to claim 14, wherein each of the curing reaction participants comprises a self-curing reactant, and the conductive particles are dispersed in the self-curing reactant; and
wherein the method further comprises:
providing at least part of the self-curing reactant on one end of the first connecting electrode facing the second connecting electrode without connecting to the self-curing reactant on an adjacent first connecting electrode; and/or,
providing at least part of the self-curing reactant on an end of the second connecting electrode facing the first connecting electrode without connecting to the self-curing reactant on an adjacent second connecting electrode.

16. The method according to claim 15, wherein the self-curing reactant is a self-curing epoxy.

17. The method according to claim 14, wherein each of the curing reaction participants comprises a curing reactant and a curing agent; and the conductive particles are dispersed in the curing agent, and/or, the conductive particles are dispersed in the curing reactant.

18. The method according to claim 17, wherein laminating the light-emitting device with the substrate, so that the curing reaction participants between the first connecting electrode and the second connecting electrode form the connecting structure, comprises:
laminating the light-emitting device with the substrate, so that at least the curing reactant located between the first connecting electrode and the second connecting electrode is in contact with the curing agent, and the curing reactant in contact with the curing agent forms the connecting structure.

19. The method according to claim 18, wherein the providing the curing reaction participants in which conductive particles are dispersed, comprises:
providing the curing agent on one end of the first connecting electrode facing the second connecting electrode; dispersing the conductive particles in the curing agent without connecting the curing agent of an adjacent first connecting electrode; or,
providing the curing agent on one end of the second connecting electrode facing the first connecting electrode; and dispersing the conductive particles in the curing agent without connecting the curing agent of an adjacent second connecting electrode.

20. The method according to claim 19, wherein the providing the curing reaction participants in which conductive particles are dispersed, further comprises:
providing a curing reactant;
providing at least part of the curing reactant on one end of the second connecting electrode facing the first connecting electrode when the curing agent is provided on one end of the first connecting electrode facing the second connecting electrode; and
providing at least part of the curing reactant on one end of the first connecting electrode facing the second connecting electrode when the curing agent is provided on one end of the second connecting electrode facing the first connecting electrode.

21. The method according to claim 20, wherein
the providing at least part of the curing reactant on one end of the second connecting electrode facing the first connecting electrode, comprises: providing the curing reactant to cover a plurality of second connecting electrodes; and
the providing at least part of the curing reactant on one end of the first connecting electrode facing the second connecting electrode, comprises: providing the curing reactant to cover a plurality of first connecting electrodes.

22. The method according to claim 21, further comprising:
after laminating the light-emitting device and the substrate to form a curing structure by the curing reaction participants located between the first connecting electrode and the second connecting electrode, removing the curing reactant that is not solid between adjacent light-emitting devices.

23. The method according to claim 17, wherein the curing reactant is an epoxy curing reactant, and the curing agent is an aliphatic amine curing agent.
